(19) United States
(12) Patent Application Publication
(10) Pub. No.: US 2014/0224297 A1
(43) Pub. Date: Aug. 14, 2014

(54) THERMOELECTRIC CONVERSION ELEMENT AND METHOD OF PRODUCING THE SAME

(71) Applicant: FUJIFILM Corporation, Tokyo (JP)

(72) Inventors: Naoyuki HAYASHI, Ashigarakami-gun (JP); Toshiaki AOAI, Ashigarakami-gun (JP); Yoshinori HOTTA, Ashigarakami-gun (JP)

(73) Assignee: FUJIFILM CORPORATION, Tokyo (JP)

(21) Appl. No.: 14/253,542

(22) Filed: Apr. 15, 2014

Related U.S. Application Data
(63) Continuation of application No. PCT/JP2012/076971, filed on Oct. 18, 2012.

(30) Foreign Application Priority Data
Oct. 19, 2011 (JP) 2011-229554
Oct. 19, 2011 (JP) 2011-229555

(51) Int. Cl. H01L 35/22; H01L 35/34

(52) U.S. Cl. CPC H01L 35/22; H01L 35/34
USPC 136/230; 438/54; 136/201

(57) ABSTRACT

A thermoelectric conversion element formed by laminating, on a substrate having a porous anodic oxidation film of aluminum, a thermoelectric conversion layer which contains an inorganic oxide semiconductor or an element having a melting point of 300° C. or higher, as a main component, and which has a void structure; and a method of producing the same.

### CROSS-REFERENCE TO RELATED APPLICATIONS

This application is a continuation of PCT/JP2012/076971 filed on Oct. 18, 2012 which claims benefit of Japanese Patent Application No. 2011-229554 filed on Oct. 19, 2011 and Japanese Patent Application No. 2011-229555 filed on Oct. 19, 2011, the subject matters of which are incorporated herein by reference in their entirety.

### FIELD OF THE INVENTION

The present invention relates to a thermoelectric conversion element and a method of producing the same.

### BACKGROUND OF THE INVENTION

Thermoelectric conversion materials that are capable of converting heat energy and electric energy are used in thermoelectric power generation elements or thermoelectric conversion elements such as a Peltier device. Thermoelectric power generation in which a thermoelectric conversion material or a thermoelectric conversion element is applied, is advantageous in that heat energy can be converted directly to electric power, and no movable parts are needed. Thus, thermoelectric power generation is used in wrist watches that are operated by body temperature, power sources for remote places, power sources for space, and the like.

Regarding the thermoelectric conversion materials, various metal materials have been suggested, and for example, it has been reported that a thin film formed from indium oxide and a palladium compound exhibits thermoelectric conversion characteristics (Non-Patent Literature 1). Furthermore, it has been reported that a thin film obtained by forming a film of zinc antimonide by a sputtering method on a quartz substrate exhibits thermoelectric conversion characteristics (Non-Patent Literature 2).

In order to enhance the thermoelectric conversion performance, attempts have been made to search for a new thermoelectric conversion material or to improve elements. The thermoelectric conversion performance varies depending on Seebeck coefficient, electrical conductivity and thermal conductivity of the thermoelectric conversion material, and as the Seebeck coefficient and electrical conductivity are higher, and as the thermal conductivity is smaller, the thermoelectric conversion performance is enhanced.

It is reported in Non-Patent Literature 3 that when a film of a BiSbTe material is formed by a flash deposition method on an anodized aluminum substrate, a porous thin film is obtained, and the relevant thin film has decreased thermal conductivity compared with a thin film formed of the same metal material on a quartz substrate. However, the electrical conductivity and Seebeck coefficient are decreased as compared with the case of using a quartz substrate.

### CITATION LIST

### Non-Patent Literatures

Non-Patent Literature 1: O. T. Gregory et al.,“Thermoelectric power factor of In₂O₃:Pd nanocomposite films”, Applied Physics Letters, Vol.99, 013107, 2011
Non-Patent Literature 2: K. Ito et al.,“Low Thermal Conductivity and Related Thermoelectric Properties of Zn₄Sb₃ and CoSb₃ Thin Films”, Mat. Res. Soc. Symp. Proc., Vol. 793, 2004, S5.1.1
Non-Patent Literature 3: M. Kashiwagi et al., “Enhanced figure of merit of a porous thin film of bismuth antimony telluride”, Applied Physics Letters, Vol.98, 023114, 2011

### SUMMARY OF THE INVENTION

### Problems that the Invention is to Solve

The present invention is contemplated for providing a thermoelectric conversion element having excellent thermoelectric conversion performance, and a method of producing the element.

### Means to Solve the Problem

Under such circumstances, the inventors of the present invention conducted a thorough investigation in order to enhance the performance of thermoelectric conversion elements. As a result, the inventors found that when a film of a material formed of an inorganic oxide semiconductor or an element having a high melting point is formed on an aluminum substrate having a porous anodic oxidation film to form a thermoelectric conversion layer, a void structure is formed in the thermoelectric conversion layer so that thermal conductivity is decreased, and excellent electrical conductivity and Seebeck coefficient are also obtained. The present invention has been made based on this finding.

According to the present invention, there is provided the following means:
<1> A thermoelectric conversion element formed by laminating, on a substrate having a porous anodic oxidation film of aluminum,

a thermoelectric conversion layer which contains an inorganic oxide semiconductor or an element having a melting point of 300° C. or higher, as a main component, and which has a void structure.
<2> The thermoelectric conversion element according to the item <1>, wherein the inorganic oxide semiconductor contains indium.
<3> The thermoelectric conversion element according to the item <1>, wherein the inorganic oxide semiconductor is selected from the group consisting of In₂O₃, SnO₂, ZnO, SrTiO₃, WO₃, MoO₃, In₂O₃—SnO₂, fluorine-doped tin oxide, antimony-doped tin oxide, antimony-doped zinc oxide, gallium-doped zinc oxide, In₂O₃—ZnO, and gallium-doped In₂O₃—ZnO.
<4> The thermoelectric conversion element according to the item <1>, wherein the thermoelectric conversion layer contains an element having a melting point of 330° C. or higher as a main component.
<5> The thermoelectric conversion element according to any one of the item <1> or <4>, wherein the thermoelectric conversion layer contains an alloy selected from the group consisting of Zn₄Sb₃, CoSb₃, MnSi_{1.75}, Mg₂Si, SiGe and FeSi₂ as a main component.
<6> The thermoelectric conversion element according to any one of the items <1> to <5>, wherein an opening ratio of the porous anodic oxidation film satisfies the following numerical expression (I):

Numerical expression (I)

Opening ratio=φ/P>0.5
wherein φ represents an average pore diameter; and P represents an average pore spacing.
<7> The thermoelectric conversion element according to any one of the items <1> to <6>, wherein the average pore diameter of the pores of the porous anodic oxidation film is 60 nm or larger.
<8> A method of producing a thermoelectric conversion element, comprising a step of forming a film of a thermoelectric conversion material which contains an inorganic oxide semiconductor or an element having a melting point of 300° C. or higher as a main component, on a substrate having a porous anodic oxidation film of aluminum, to form a thermoelectric conversion layer.
<9> The method of producing a thermoelectric conversion element according to the item <8>, comprising steps of;

forming a film of a thermoelectric conversion material which contains an element having a melting point of 300° C. or higher as a main component, on a substrate having a porous anodic oxidation film of aluminum, to form a thermoelectric conversion layer; and

annealing the thermoelectric conversion layer.
<10> The method of producing a thermoelectric conversion element according to the item <8>, comprising a step of forming a film of a thermoelectric conversion material which contains an element having a melting point of 300° C. or higher as a main component, at a substrate temperature of 150° C. or higher, on a substrate having a porous anodic oxidation film of aluminum, to form a thermoelectric conversion layer.
<11> The method of producing a thermoelectric conversion element according to any one of the items <8> to <10>, comprising a step of anodizing an aluminum plate with oxalic acid, to obtain the substrate having the porous anodic oxidation film.
<12> The method of producing a thermoelectric conversion element according to any one of the items <8> to <11>, wherein the film forming process is carried out by a vapor phase deposition method.

### Effects of the Invention

The thermoelectric conversion element of the present invention exhibits excellent thermoelectric conversion performance, and can be suitably used in various articles for thermoelectric power generation. Furthermore, according to the method of producing a thermoelectric conversion element of the present invention, a thermoelectric conversion element having excellent thermoelectric conversion performance is obtained.

Other and further features and advantages of the invention will appear more fully from the following description, appropriately referring to the accompanying drawings.

### BRIEF DESCRIPTION OF THE DRAWINGS

{FIG. 1}

FIG. 1 is a schematic diagram illustrating an example of the thermoelectric conversion element of the present invention.

{FIG. 2}

FIG. 2 is a partial cross-sectional diagram of an anodic oxidation film of aluminum.

{FIG. 3}

FIG. 3 is a diagram schematically illustrating the process of forming a film of a thermoelectric conversion material on an anodic oxidation film.

### MODE FOR CARRYING OUT THE INVENTION

The thermoelectric conversion element of the present invention is formed by laminating, on a substrate having a porous anodic oxidation film of aluminum, a thermoelectric conversion layer containing an inorganic oxide semiconductor or an element having a melting point of 300° C. or higher as a main component. When the thermoelectric conversion layer is formed on the porous layer of an anodized aluminum film, a void structure is generated in the thermoelectric conversion layer, and a decrease in the thermal conductivity of the layer can be realized. Furthermore, when the inorganic oxide semiconductor or the element having a high melting point is used as a main component of the thermoelectric conversion layer, electrical conductivity and Seebeck coefficient can also be increased.

A thermoelectric conversion element utilizes the Seebeck effect for thermoelectric conversion, and as an indicator representing the thermoelectric conversion performance, a thermoelectric figure of merit Z represented by the following numerical expression (A) is used.

### Numerical Expression (A): Z=S² σ/κ

S(V/K): Thermopower (Seebeck coefficient)

σ(S/m): Electrical conductivity

κ(W/mK): Thermal conductivity

In the numerical expression (A), S represents Seebeck coefficient; σ represents electrical conductivity; and κ represents thermal conductivity. The Seebeck coefficient is the thermopower per absolute temperature of 1 K.

In order to enhance the thermoelectric conversion performance of the element, it is required to decrease the thermal conductivity κ by increasing the absolute value of Seebeck coefficient S and the electrical conductivity σ of the thermoelectric conversion layer or the thermoelectric conversion material.

In the thermoelectric conversion element of the present invention, the thermoelectric conversion layer has a void structure, and thereby decreasing thermal conductivity. In general, when pores and the like are present in the layer, thermal conductivity is decreased, while electric resistivity is also increased and thereby decreasing electrical conductivity. In the present invention, the inorganic oxide semiconductor or the element having a particular melting point is used as the material of the thermoelectric conversion layer, and as a result, the thermoelectric conversion layer can exhibit excellent electrical conductivity and excellent Seebeck coefficient while retaining a void structure. The thermoelectric conversion element of the present invention can exhibit excellent thermoelectric conversion performance by a synergistic effect of these thermal conductivity, electrical conductivity and Seebeck coefficient.

Furthermore, in the present invention, the substrate having a porous anodic oxidation film of aluminum is used, and as a result, the element can exhibit excellent adhesiveness between the substrate and the thermoelectric conversion layer. When the adhesiveness between the substrate and the thermoelectric conversion layer is enhanced, warpage of the substrate or cracks caused by detachment can be suppressed. As a result, thermoelectric conversion performance can be more improved.

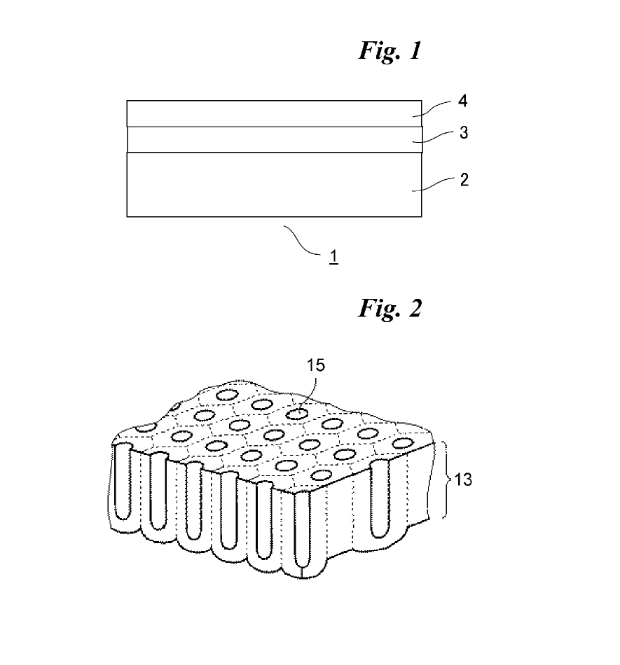

An example of the thermoelectric conversion element of the present invention is shown in FIG. 1. The thermoelectric conversion element 1 has an aluminum substrate 2; an anodic oxidation film 3 formed on the surface of the substrate; and a thermoelectric conversion layer 4 formed on the anodic oxidation film. The thermoelectric conversion element of the present invention may also have, in addition to the substrate and the thermoelectric conversion layer, electrodes that electrically connect these. As illustrated in FIG. 2, the substrate has a porous anodic oxidation film 13 of aluminum. The anodized aluminum film 13 has formed therein micropores 15 which have a cross-section shape of approximately a straight pipe shape and are arranged in a honeycomb shape.

Hereinafter, the present invention will be described in detail with appropriate reference to these drawings.

### [Substrate]

The substrate of the thermoelectric conversion element of the present invention is desirably a substrate having a porous anodic oxidation film of aluminum. Such a substrate is obtained by anodizing an aluminum substrate and forming an anodic oxidation film on the surface of the substrate. The anodized aluminum film is composed of a barrier layer, which is a basal layer, and a porous layer formed thereon. The porous layer has plural fine pores (micropores) that are regularly arranged (see FIG. 2). The thermoelectric conversion element of the present invention has the thermoelectric conversion layer formed on this porous layer.

The anodized aluminum film formed by anodizing is capable of standing by itself, and the film can be removed from the aluminum plate as a base after the anodizing treatment. As the substrate of the element, only the film portion may be used, or an aluminum plate having an anodic oxidation film formed on the surface may be used.

Hereinafter, a method for producing a porous anodic oxidation film of aluminum will be described.

### <Aluminum Substrate>

The aluminum substrate is not particularly limited, and examples include a pure aluminum plate; alloy plates composed primarily of aluminum and containing trace amounts of other elements; substrates made of low-purity aluminum (e.g., recycled material) on which high-purity aluminum has been vapor-deposited; substrates such as silicon wafers, quartz or glass whose surface has been covered with high-purity aluminum by a process such as vapor deposition or sputtering; and resin substrates on which aluminum has been laminated.

Regarding the aluminum substrate, it is preferable that the aluminum of the surface that is subjected to an anodizing treatment have higher purity. Specifically, the aluminum purity is preferably 99.5% by mass or higher, more preferably 99.9% by mass or higher, and further preferably 99.99% by mass or higher. When the aluminum purity is in the above range, the order of arrangement of the micropores (fine pores) formed at the surface of the anodized aluminum film is improved, which is preferable.

The aluminum substrate may be subjected to a pretreatment before the anodizing treatment. For example, it is preferable to perform a heat treatment in advance, in order to enhance regularity of the pore arrangement. Furthermore, it is preferable that the surface that is subjected to the anodizing treatment in the aluminum substrate be subjected to a degreasing treatment and a mirror surface finishing treatment in advance.

### <Heat Treatment>

The heat treatment is preferably carried out at 200° C. to 350° C. for about 30 seconds to 2 minutes. Specifically, a method of heating the aluminum substrate by placing the substrate in a heated oven may be used. When the aluminum substrate is subjected to such a heat treatment, the micropores formed on the surface of the anodic oxidation film can be orderly arranged.

The aluminum substrate after the heat treatment is preferably cooled rapidly. Examples of the cooling method include a method of directly immersing the substrate into water or the like.

### <Degreasing Treatment>

The degreasing treatment is a treatment of removing, by dissolving, organic components such as dust, grease and resins, and the like that are adhering to the aluminum substrate surface, using an acid, an alkali, an organic solvent or the like. This treatment is carried out for the purpose of preventing the occurrence of defects caused by organic components in the various treatments that will be described below.

Examples of the method of degreasing treatment include a method in which an organic solvent such as an alcohol (e.g., methanol), ketone (e.g., methyl ethyl ketone), benzine or volatile oil is contacted with the surface of the aluminum substrate at ambient temperature (organic solvent method); a method in which a liquid containing a surfactant such as soap or a neutral detergent is contacted with the surface of the aluminum substrate at a temperature of from ambient temperature to about 80° C., after which the surface is rinsed with water (surfactant method); a method in which an aqueous sulfuric acid solution having a concentration of 10 g/L to 200 g/L is contacted with the surface of the aluminum substrate at a temperature of from ambient temperature to about 70° C. for about 30 seconds to 80 seconds, following which the surface is rinsed with water; a method in which an aqueous solution of sodium hydroxide having a concentration of 5 g/L to 20 g/L is contacted with the surface of the aluminum substrate at ambient temperature for about 30 seconds while electrolysis is carried out by passing a direct current through the aluminum substrate surface as the cathode at a current density of 1 A/dm² to 10 A/dm², following which the surface is contacted with an aqueous solution of nitric acid having a concentration of 100 g/L to 500 g/L and thereby neutralized; a method in which the surface of the aluminum substrate is contacted with any of various known anodizing electrolytic solutions at ambient temperature while electrolysis is carried out by passing a direct current at a current density of 1 A/dm² to 10 A/dm² or an alternating current through the aluminum substrate surface as the cathode; a method in which an alkaline aqueous solution having a concentration of 10 g/L to 200 g/L is contacted with the surface of the aluminum substrate at 40° C. to 50° C. for about 15 seconds to 60 seconds, following which the surface is contacted with an aqueous solution of nitric acid having a concentration of 100 g/L to 500 g/L and thereby neutralized; a method in which an emulsion prepared by mixing a surfactant, water and the like into an oil such as gas oil or kerosene is contacted with the surface of the aluminum substrate at a temperature of from ambient temperature to about 50° C., following which the surface is rinsed with water (emulsion degreasing method); and a method in which a mixed solution of, for example, sodium carbonate, phosphates and surfactant is contacted with the surface of an aluminum substrate at a temperature of ambient temperature to about 50° C. for about 30 seconds to 180 seconds, following which the surface is rinsed with water (phosphate method).

Of these, the organic solvent method, surfactant method, emulsion degreasing method and phosphate method are preferred from the standpoint of removing grease from the aluminum surface while causing substantially no aluminum dissolution.

Known degreasers may be used in degreasing treatment. For example, degreasing treatment may be carried out using any of various commercially available degreasers by the prescribed method.

### <Mirror Surface Finishing Treatment>

The mirror surface finishing treatment is carried out in order to eliminate surface unevenness of the aluminum substrate, for example, the rolling lines generated at the time of rolling of the aluminum substrate, and the like.

The method for the mirror surface finishing treatment is not particularly limited, and for example, conventional methods such as mechanical polishing, chemical polishing, and electrolytic polishing can be used.

Examples of mechanical polishing include a method of polishing using various commercially available polishing clothes; and a method of combining various commercially available polishing agents (for example, diamond and alumina) and buffs. Specifically, in the case of using a polishing agent, a method of performing polishing by changing the polishing agent used from coarse particles to fine particles over time is suitably taken as an example.

Examples of chemical polishing include various methods described in “Aluminum Handbook”, 6^{th} Edition, edited by Japan Aluminum Association, 2001, p. 164-165.

Furthermore, preferred examples include a phosphoric acid/nitric acid method, an Alupol I method, an Alupol V method, an Alcoa R5 method, a H₃PO₄—CH₃COOH—Cu method, and a H₃PO₄—HNO₃—CH₃COOH method. Among them, a phosphoric acid/nitric acid method, a H₃PO₄—CH₃COOH—Cu method, and a H₃PO₄—HNO₃—CH₃COOH method are preferred.

Suitable examples of electrolytic polishing include various methods described in “Aluminum Handbook”, 6^{th} Edition, edited by Japan Aluminum Association, 2001, p. 164-165; a method described in the specification of U.S. Pat. No. 2,708,655; and a method described in “Jitsumu Hyomen Gijutsu (Business Surface Technology)”, Vol. 33, No. 3, 1986, p. 32-38.

These methods can be used in appropriate combination. For example, it is preferable to perform mechanical polishing in which the polishing agent is changed over time from coarse particles to fine particles, and then to perform electrolytic polishing.

### <Anodizing Treatment>

The anodizing treatment of an aluminum substrate can be carried out using conventional methods. For example, a self-ordering method can be used. The self-ordering method includes utilizing the ability of an anodic oxidation film to form orderly arranged micropores and eliminating an ordered arrangement-disturbing factor to improve the order. Specifically, the self-ordering method includes providing a high-purity aluminum substrate, forming an anodic oxidation film thereon at a voltage according to the type of the electrolytic solution for a long time (for example, several hours to more than ten hours) at low speed, and then removing the film. In this method, the pore size depends on the voltage, and therefore, the desired pore size can be obtained to some extent by controlling the voltage.

According to the present invention, the anodizing treatment is preferably carried out by an anodizing treatment (a-1) described below, and it is more preferable that in addition to the anodizing treatment (a-1), a film removal treatment (a-2) and a re-anodizing treatment (a-3) be carried out in combination. The anodizing treatment (a-1), film removal treatment (a-2) and re-anodizing treatment (a-3) may be respectively carried out several times. For example, it is preferable to perform the anodizing treatment (a-1) and the film removal treatment (a-2) repeatedly several times in this order, and then to perform the re-anodizing treatment (a-3). Furthermore, the film removal treatment (a-2) may also be performed after the re-anodizing treatment (a-3).

When the above-described treatment processes are carried out repeatedly two or more times, the treatment conditions for the respective processes may be the same or may be different.

<Anodizing Treatment (a-1)>

The anodizing treatment is a treatment in which electrolysis is performed in an electrolyte solution (for example, a solution at an acid concentration of 0.01 mol/L to 5 mol/L) using an aluminum substrate as an anode, the substrate surface oxidized, and thereby a porous film of aluminum oxide is formed on the surface.

The electrolyte solution is preferably an acid solution. More preferred examples include sulfuric acid, phosphoric acid, chromic acid, oxalic acid, sulfamic acid, benzenesulfonic acid, amidosulfonic acid, glycolic acid, tartaric acid, malic acid and citric acid; more preferred examples include sulfuric acid phosphoric acid, and oxalic acid; and particularly preferred examples include oxalic acid. These acids can be used singly, or two or more kinds can be used in combination.

The pore diameter of the micropores thus formed may vary depending on the kind of the acid solution used. In the present invention, the average pore diameter of the micropores is preferably 60 nm or more. In order to obtain such a pore diameter, it is preferable to use oxalic acid as the electrolyte solution.

Since the anodizing treatment conditions vary with the electrolyte used, the treatment conditions are not defined in a generalized manner; however, in general, conditions including an electrolyte concentration of 0.01 mol/L to 5 mol/L, a solution temperature of −10° C. to 30° C., a current density of 0.01 A/dm² to 20 A/dm², a voltage of 3 V to 300 V, and an electrolysis time of 0.5 hours to 30 hours are preferred; conditions including an electrolyte concentration of 0.05 mol/L to 3 mol/L, a solution temperature of −5° C. to 25° C., a current density of 0.05 A/dm² to 15 A/dm², a voltage of 5 V to 250 V, and an electrolysis time of 1 hour to 25 hours are more preferred; and conditions including an electrolyte concentration of 0.1 mol/L to 1 mol/L, a solution temperature of 0° C. to 20° C., a current density of 0.1 A/dm² to 10 A/dm², a voltage of 10 V to 200 V, and an electrolysis time of 2 hours to 20 hours are further preferred.

The average flow rate in the anodizing treatment is preferably 0.5 m/min to 20.0 m/min, more preferably 1.0 m/min to 15.0 m/min, and further preferably 2.0 m/min to 10.0 m/min. When the anodizing treatment is carried out at the flow rate in the above range, uniform micropores having high order can be formed.

Furthermore, the method of causing the electrolyte to flow is not particular limited, but for example, a method of using a general stirring apparatus such as a stirrer is used. Particularly, it is preferable to use a stirrer which can control the stirring speed with a digital display, because the average flow rate can be controlled. Examples of such a stirring apparatus include “MAGNETIC STIRRER HS-50D (manufactured by AS ONE Corp.).

For the anodizing treatment, in addition to the method of performing the treatment at a constant voltage, a method of changing the voltage intermittently or continuously can also be used. In this case, it is preferable to lower the voltage sequentially. Thereby, the resistance of the anodic oxidation film can be decreased, and fine micropores are formed in the anodic oxidation film, which is therefore preferable.

<Film Removal Treatment (a-2)>

The film removal treatment is a treatment of removing by dissolving the anodic oxidation film formed on an aluminum substrate surface by the anodizing treatment. In the film removal treatment, the aluminum substrate is not dissolved, and only the anodic oxidation film (aluminum oxide (alumina) film) is dissolved.

In the anodic oxidation film, a portion closer to the aluminum substrate has higher order. Therefore, ordered pits can be obtained by once removing the film in such a manner that the bottom portion of the anodic oxidation film can be left on the aluminum substrate and exposed on the surface.

The film removal treatment is carried out by bringing an aluminum substrate having an anodic oxidation film formed thereon, into contact with an alumina dissolving liquid. The alumina dissolving liquid may be any solution which dissolves alumina, but substantially does not dissolve aluminum.

As the alumina dissolving liquid, an acid solution or an alkali solution can be used, and examples include aqueous solutions of acids such as sulfuric acid, phosphoric acid, nitric acid and hydrochloric acid, or a mixture thereof; and aqueous solutions of alkalis such as sodium hydroxide, potassium hydroxide and lithium hydroxide. Furthermore, an aqueous solution containing at least one selected from chromium compounds, zirconium-based compounds, titanium-based compounds, lithium salts, cerium salts, magnesium salts, sodium silicofluoride, zinc fluoride, manganese compounds, molybdenum compounds, magnesium compounds, barium compounds, and simple halogens, can also be used. A mixture of two or more kinds of these solutions may also be used as the alumina dissolving liquid.

Specific examples of the chromium compounds include chromium(III) oxide and anhydrous chromic(VI) acid.

Examples of the zirconium-based compounds include zirconium ammonium fluoride, zirconium fluoride, and zirconium chloride.

Examples of the titanium compounds include titanium oxide and titanium sulfide.

Examples of the lithium salts include lithium fluoride and lithium chloride.

Examples of the cerium salts include cerium fluoride and cerium chloride.

Examples of the magnesium salts include magnesium sulfide.

Examples of the manganese compounds include sodium permanganate and calcium permanganate.

Examples of the molybdenum compounds include sodium molybdenate.

Examples of the magnesium compounds include magnesium fluoride pentahydrate.

Examples of the barium compounds include barium oxide, barium acetate, barium carbonate, barium chlorate, barium chloride, barium fluoride, barium iodide, barium lactate, barium oxalate, barium perchlorate, barium selenate, barium selenite, barium stearate, barium sulfite, barium titanate, barium hydroxide, barium nitrate, and hydrates thereof. Among the above-mentioned barium compounds, barium oxide, barium acetate, and barium carbonate are preferred, and barium oxide is particularly preferred.

Examples of the simple halogens include chlorine, fluorine and bromine.

Among them, an aqueous solution containing an acid is preferably used, and preferred examples of the acid include sulfuric acid, phosphoric acid, nitric acid, and hydrochloric acid. A mixture of two or more kinds of acids may also be used.

The acid concentration of the aqueous acid solution is preferably 0.01 mol/L or more, more preferably 0.05 mol/L or more, and further preferably 0.1 mol/L or more. The upper limit of the acid concentration is not particularly limited, but generally, the upper limit is preferably 10 mol/L or less, more preferably 5 mol/L or less, and further preferably 1 mol/L or less. An unnecessarily high concentration is not economically efficient, and if the concentration is higher, there is a risk that the aluminum substrate may be dissolved.

The temperature of the alumina dissolving liquid is preferably −10° C. or higher, more preferably −5° C. or higher, and further preferably 0° C. or higher. The alumina dissolving liquid is preferably used without being boiled, because if a boiling alumina dissolving liquid is used in the treatment, the start points for ordering will be destroyed and disturbed.

When an aqueous acid solution is used as the alumina dissolving liquid, the temperature of the aqueous acid solution is preferably 20° C. to 60° C.

There are no particular limitations on the method for bringing an aluminum substrate having an anodic oxidation film formed thereon into contact with an alumina dissolving liquid, and examples include a dipping method and a spraying method. Among them, a dipping method is preferred.

The dipping method is a treatment of dipping an aluminum substrate having an anodic oxidation film formed thereon, in an alumina dissolving liquid. When stirring is performed at the time of the dipping treatment, it is preferable because a uniform treatment is achieved.

The time for the dipping treatment is preferably 10 minutes or longer, more preferably 1 hour or longer, and further preferably 3 hours or longer, or 5 hours or longer.

Furthermore, the amount of dissolution of the anodic oxidation film is preferably 0.001% to 50% by mass, more preferably 0.005% to 30% by mass, and further preferably 0.01% to 15% by mass, of the total amount of the anodic oxidation film. When the amount of dissolution is in the above range, the portion having disordered pore arrangement in the surface of the anodic oxidation film is dissolved, and the order of the arrangement of the micropores can be improved, and also, the bottom portion of the anodic oxidation film having micropores, which will serve as start points in the re-anodizing treatment (a-3), are left.

<Re-Anodizing Treatment (a-3)>

After the film removal treatment in which the anodic oxidation film is removed and pits are orderly formed on the surface of the aluminum substrate, it is preferable to apply an anodizing treatment again to the substrate. By this process, an anodic oxidation film having a higher order of micropores can be obtained.

The re-anodizing treatment can be carried out using a conventional method, but it is preferable to carry out the treatment under the same conditions as those for the anodizing treatment (a-1) described above.

Furthermore, a method of repeating turning-on and turning-off of the current intermittently while setting the direct current voltage to be constant; and a method of repeating turning-on and turning-off of the current while intermittently changing the direct current voltage, can also be suitably used. These methods are preferable, because fine micropores are generated in the anodic oxidation film, and uniformity of the pore diameter is enhanced.

When the re-anodizing treatment is carried out at a low temperature, the arrangement of micropores becomes regular, and the pore diameter is also made uniform. On the other hand, when the re-anodizing treatment is carried out at a relatively high temperature, the arrangement of micropores is disturbed, and fluctuation of the pore diameter can be adjusted to a desired range. Also, the fluctuation of the pore diameter can be controlled by the treatment time.

The increment of the thickness of the anodic oxidation film caused by the re-anodizing treatment is preferably 0.1 μm to 100 μm, and more preferably 0.5 μm to 50 μm. When the increment is in the above range, the order of the arrangement of pores can be further improved.

### <Aluminum Removal Treatment>

If necessary, the aluminum substrate may be removed from the anodic oxidation film formed on the surface of the aluminum substrate by the anodizing treatment. The substrate of the element used in the present invention may be any substrate having at least a porous anodic oxidation film, and it is not necessarily for the substrate to have an aluminum portion. The removal of the aluminum substrate can be carried out by a conventional method. For example, a method of removing only the aluminum substrate by dissolving using a treatment liquid which does not dissolve an anodic oxidation film (alumina) and can easily dissolve aluminum, may be used.

The anodized aluminum film used in the present invention is preferably such that the film thickness is 6 μm or more.

Furthermore, the opening ratio of the porous layer of the anodic oxidation film is preferably 0.5 or higher. The opening ratio is the ratio of the pore diameter with respect to the pore spacing, which is calculated by the following numerical expression (I):

Numerical expression (I) Opening ratio=φ/P>0.5

In numerical expression (I), φ represents the average pore diameter of the fine pores (micropores) of the porous layer; and P represents the average pore spacing. The pore diameter means the diameter of pores (opening sections) formed in the porous layer, and the average pore diameter φ is an average value thereof. The pore spacing means the distance between the centers of two adjacent pores (opening sections) of the porous layer, and the average pore spacing P is an average value thereof.

In the present invention, the average pore diameter φ of the porous layer is preferably 60 nm or more. Furthermore, the average pore spacing P is preferably 100 nm or more.

The thermoelectric conversion element of the present invention is produced by forming the thermoelectric conversion layer on this porous layer of the anodic oxidation film. At the time of forming the thermoelectric conversion layer, the porous layer of the anodic oxidation film serves as a scaffold on which the thermoelectric conversion material, i.e. the inorganic oxide or the high melting point element as a main component, is deposited and laminated. When the thermoelectric conversion material is deposited by using the porous layer as a scaffold, a void structure corresponding to the size of the pore diameter, the pore spacing, and the shape of the pores is formed in the thermoelectric conversion layer (hereinafter, referred to as a void structure of the thermoelectric conversion layer according to the present invention).

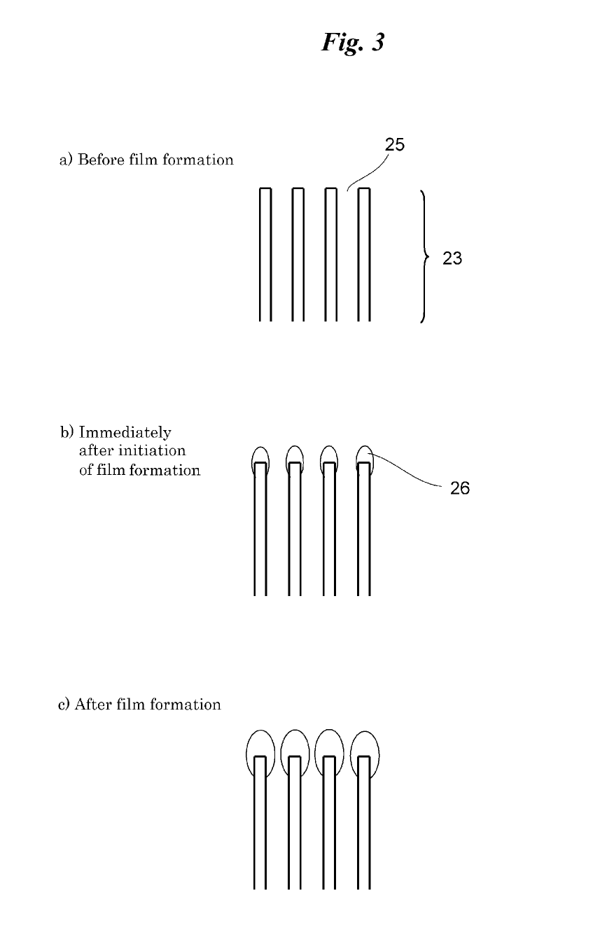

FIG. 3 schematically illustrates the process in which a layer of a thermoelectric conversion material is formed on a porous layer of an anodic oxidation film. FIG. 3a) is a schematic diagram of the upper part of the anodic oxidation film (opening section) before the film forming of the thermoelectric conversion material. The anodic oxidation film 23 has a plural number of micropores 25. The thermoelectric conversion material 26 is gradually deposited on the surface of the anodic oxidation film 23 (FIG. 3b), and thus a thermoelectric conversion layer is formed (FIG. 3c).

The position, size, shape and the like of the void structure of the thermoelectric conversion layer may affect the decrease in thermal conductivity to some extent. As described above, the void structure of the thermoelectric conversion layer is defined according to the pore diameter, pore spacing, pore shape and the like of the porous layer (hereinafter, pore diameter and the like). Therefore, the void structure of the thermoelectric conversion layer can be regulated by controlling the pore diameter and the like of the porous layer. When the opening ratio or the pore diameter of the porous layer is adjusted to the above-described preferred range, a decrease in thermal conductivity can be realized more effectively. The void structure of the thermoelectric conversion layer is such that the average pore diameter is preferably 1 nm to 100 nm, and more preferably 5 nm to 60 nm.

In the thermoelectric conversion layer of the element of the present invention, any one of an inorganic oxide semiconductor and an element having a melting point of 300° C. or higher is used as a main component.

### [Inorganic Oxide]

The inorganic oxide semiconductor used in the thermoelectric conversion layer is preferably an inorganic oxide semiconductor containing indium. Furthermore, the inorganic oxide semiconductor may also be a doped semiconductor. When such an inorganic oxide semiconductor is used, a decrease in the thermal conductivity of the thermoelectric conversion layer and an increase in the electrical conductivity and Seebeck coefficient can be realized.

The inorganic oxide semiconductor is preferably contained in the thermoelectric conversion layer in an amount of 90% by mass or more. Preferably, the oxide is contained in an amount of 95% by mass or more, and more preferably 98% by mass or more.

Specific examples of the inorganic oxide semiconductor include In₂O₃, SnO₂, ZnO, SrTiO₃, WO₃, MoO₃, In₂O₃—SnO₂ (ITO), fluorine-doped tin oxide (FTO), antimony-doped tin oxide (ATO), antimony-doped zinc oxide (AZO), gallium-doped zinc oxide (GZO), In₂O₃—ZnO (IZO), and gallium-doped In₂O₃—ZnO (IGZO). Preferably, the inorganic oxide semiconductor includes In₂O₃—SnO₂ (ITO), In₂O₃—ZnO (IZO), and gallium-doped In₂O₃—ZnO (IGZO).

Furthermore, it is preferable that the thermoelectric conversion layer containing the inorganic oxide semiconductor as a main component substantially do not contain tellurium (Te) as a main component or one of other components described below. Since tellurium is sublimable, if tellurium is contained in the conversion layer, the composition of the layer changes over time, which is not preferable. Specifically, the content of tellurium is preferably 5% by mass or less of the thermoelectric conversion layer.

### [High Melting Point Material]

The element having a melting point of 300° C. or higher that is used in the thermoelectric conversion layer is preferably an element having a melting point of 330° C. or higher. When the element having such high melting point is used, a decrease in the thermal conductivity of the thermoelectric conversion layer and an increase in the electrical conductivity and Seebeck coefficient can be realized.

One kind or two or more kinds of the element having a melting point of 300° C. or higher can be used as a main component. It is preferable that the element having a melting point of 300° C. be contained in an amount of 90% by mass or more in total of the thermoelectric conversion layer. Preferably, the relevant element is contained in an amount of 95% by mass or more in total, and more preferably in an amount of 98% by mass or more.

Specific examples of the element that is used as a main component of the thermoelectric conversion layer include Zn (melting point: 419° C.), Sb (melting point: 630° C.), Co (melting point: 1495° C.), Mn (melting point: 1244° C.), Si (melting point: 1410° C.), Mg (melting point: 650° C.), Ge (melting point: 938° C.), and Fe (melting point: 1538° C.). The thermoelectric conversion layer of the present invention preferably contains an alloy formed from two or more kinds of these elements, as a main component. Specific examples of preferred alloys include Zn₄Sb₃, CoSb₃, MnSi_{1.75}, Mg₂Si, SiGe, and FeSi₂.

Furthermore, it is preferable that the thermoelectric conversion layer containing the element having a melting point of 300° C. or higher as a main component substantially do not contain tellurium (Te (melting point: 449° C.)) as a main component or one of other components described below. Since tellurium is sublimable, if tellurium is contained in the conversion layer, the composition of the layer changes over time, which is not preferable. Specifically, the content of tellurium is preferably 10% by mass or less of the thermoelectric conversion layer.

### [Other Components]

The thermoelectric conversion layer may contain a dopant and the like, in addition to the main components.

When the thermoelectric conversion layer contains a dopant, the dopant can be appropriately selected according to the kind of the main component, i.e. the inorganic oxide semiconductor or the element having a melting point of 300° C. or higher.

The content of the other components is preferably 10% by mass or less of the thermoelectric conversion layer.

Furthermore, when the thermoelectric conversion layer contains the element having a melting point of 300° C. or higher as a main component, an element having a melting point of lower than 300° C. can also be contained in the thermoelectric conversion layer as the other component. In this case, a smaller content of the element having a melting point of lower than 300° C. is preferred, from the viewpoint of electrical conductivity or the like. The content of the element having a melting point of lower than 300° C. is preferably 10% by mass or less, and more preferably 5% by mass or less, of the thermoelectric conversion layer.

### [Forming of Thermoelectric Conversion Layer]

The thermoelectric conversion layer is formed on the porous anodic oxidation film of aluminum by forming a film of the thermoelectric conversion material containing the inorganic oxide semiconductor or the element having a melting point of 300° C. or higher as a main component (FIG. 1). The porous layer of the anodic oxidation film has plural micropores, as described above. Therefore, when the film of a thermoelectric conversion material is formed thereon, a void structure similar to a pore structure of the porous layer can be formed in the thermoelectric conversion layer (FIG. 3).

Film formation of the thermoelectric conversion layer is preferably carried out by a vapor phase deposition method. Hereinafter, a method for forming a thermoelectric conversion layer according to a vapor phase deposition method will be explained.

The vapor phase deposition method is not particularly limited, and any method capable of forming a thermoelectric conversion film by depositing, on a substrate, raw materials for forming the thermoelectric conversion layer containing the inorganic oxide semiconductor or the element having a melting point of 300° C. or higher as a main component, may be used. For example, physical vapor deposition methods such as a pulse laser deposition method, a sputtering method, a vacuum deposition method, an electron beam deposition method, an ion plating method, a plasma assisted deposition method, an ion assisted deposition method, a reactive deposition method, a laser ablation method, and an aerosol deposition method; and chemical vapor phase growth methods such as a thermal CVD method, a catalytic chemical vapor phase growth method, a plasma CVD method, and an organic metal vapor phase growth method, can be suitably employed. Among these methods, a sputtering method and an ion plating method are preferred.

The film thickness of the thermoelectric conversion layer thus formed is preferably 50 nm or more, and more preferably 200 nm or more. If the film thickness is small, it is difficult to impart a temperature difference, and the resistance in the film is increased, which is not preferable.

### (1) Formation of Thermoelectric Conversion Layer Containing Inorganic Oxide Semiconductor as Main Component

As the raw materials for forming the thermoelectric conversion layer containing the inorganic oxide semiconductor as a main component (hereinafter, “raw material”), any materials which can form an inorganic oxide by being vaporized according to a vapor phase deposition method and being deposited on a substrate, can be used without any particular limitations. For example, metals or non-metal elements, oxides, and various compounds (carbonates and the like) that contain the constituent elements of the intended inorganic oxide, can be used. Furthermore, mixtures thereof may also be used. When the thermoelectric conversion layer contains two or more kinds of inorganic elements, it is preferable to use a raw material prepared by mixing materials containing the respective elements in advance, from the viewpoint of the ease of handling.

As the substrate, the above-described substrate having the porous anodic oxidation film of aluminum is used.

These raw materials can be mixed so as to obtain the composition ratio of an intended inorganic oxide and used directly, but particularly, it is preferable to use these materials after mixing and baking. The baked material is easy to handle at the time of vapor phase deposition.

There are no particular limitations on the conditions for the baking of the raw material, and the raw material may be baked at a high temperature at which crystals of the inorganic oxide are formed, or may be baked at a relatively low temperature to the extent that crystals of the inorganic oxide are not produced, but a calcination product is formed. The means of baking is not particularly limited, and any arbitrary means such as an electric heating furnace or a gas heating furnace can be employed. The baking atmosphere may be usually an oxidizing atmosphere such as in an oxygen gas stream or in air. The baking can also be carried out in an inert atmosphere.

When the inorganic oxide semiconductor is used as a main component, film formation of the thermoelectric conversion layer by vapor phase deposition may be carried out at room temperature, or may be carried out by heating the substrate.

### (2) Formation of Thermoelectric Conversion Layer Containing Element Having Melting Point of 300° C. or Higher as Main Component

As the raw materials for forming the thermoelectric conversion layer containing the element having a melting point of 300° C. or higher as a main component (hereinafter, “raw material”), any materials which can form a thermoelectric conversion film containing the element having a melting point of 300° C. or higher as a main component, by being vaporized according to a vapor phase deposition method and being deposited on a substrate, can be used without any particular limitations. For example, a metal containing an element having a melting point of 300° C. or higher as a component can be used. When the main component is composed of two or more kinds of elements, a mixture of raw materials containing these components may also be used.

As the substrate, the above-described substrate having the porous anodic oxidation film of aluminum is used.

These raw materials can be mixed so as to obtain the composition ratio of an intended alloy and used directly, but particularly, it is preferable to use these materials after mixing and baking. The baked material is easy to handle at the time of vapor phase deposition.

When the element having a melting point of 300° C. or higher is used as a main component, film formation of the thermoelectric conversion layer by vapor phase deposition may be carried out at room temperature, or may be carried out by heating the substrate to about 150° C. to 350° C. When deposition and film formation are carried out without heating the substrate, the degree of crystallization of the components is very low, and satisfactory thermoelectric conversion performance may not be exhibited. Therefore, it is necessary to perform an annealing treatment that will be described below after film formation. When deposition is carried out by heating the substrate, the components are produced in a crystallized state on the substrate. Therefore, the annealing treatment may not be carried out, but it is also acceptable to perform the annealing treatment in addition. By heating the substrate, or by performing the annealing treatment after film formation, crystallization of the components proceeds, and satisfactory thermoelectric conversion performance can be exhibited.

At the time of formation of the thermoelectric conversion layer containing the element having a melting point of 300° C. or higher as a main component, a treatment of proceeding crystallization of the components (crystallization treatment) is required in order to enhance the thermoelectric conversion performance. The crystallization treatment can be carried out by performing film formation by setting the substrate temperature to a high temperature, or by an annealing treatment after film formation. When an element having a low melting point is used as a main component of the thermoelectric conversion layer, the crystallization treatment causes melting of the element, and the void structure in the conversion layer is lost. In the present invention, by using the element having a melting point of 300° C. or higher as a main component of the conversion layer, the thermal conductivity can be decreased by maintaining the void structure of the conversion layer, and the thermoelectric conversion performance can be enhanced by sufficient crystallization.

Furthermore, the present invention employs the substrate having a porous anodic oxidation film of aluminum, and therefore the thermoelectric conversion element has excellent adhesiveness between the substrate and the thermoelectric conversion layer. By enhancing the adhesiveness between the substrate and the thermoelectric conversion layer, warpage of the substrate or cracks caused by detachment can be suppressed, and satisfactory thermoelectric conversion performance can be exhibited.

The temperature of the annealing treatment is preferably about 350° C. to 500° C. When the annealing treatment is carried out in this temperature range, crystallization proceeds in the thermoelectric conversion film, and thereby obtain the thermoelectric conversion film having a good thermoelectric conversion performance. If the annealing treatment temperature is too low, the crystallization does not sufficiently proceed, and therefore the thermoelectric conversion performance is deteriorated, which is not preferable. On the other hand, if the annealing treatment temperature is too high, different phases appear, and also, the thermoelectric conversion performance is deteriorated, which is not preferable.

At the time of the annealing treatment, it is preferable to employ an inert gas atmosphere. As the inert gas, argon, helium, or nitrogen gas can be used. Further, argon/hydrogen gas, nitrogen/hydrogen gas, or the like can be used when reduction of the thermoelectric conversion film is carried out. The pressure at this time is not particularly limited, and any of a reduced pressure, atmospheric pressure, and an added pressure may be employed.

The time for the annealing treatment may vary depending on the size, thickness or the like of the thermoelectric conversion film, but it is preferable to carry out the treatment until crystallization of the thermoelectric conversion film has sufficiently proceeded. The treatment time may be usually from about 10 minutes to 12 hours, and preferably from 1 hour to 4 hours.

The thermoelectric conversion element of the present invention can be suitably used in applications such as power generation utilizing hot spring heat, power sources for wrist watches, semiconductor driving power sources, power sources for small-sized sensors, power generation utilizing solar heat, and power generation utilizing waste heat.

### EXAMPLES

The present invention will be described in more detail based on the following examples, but the invention is not intended to be limited thereto.

### Production Example 1

### Production of Anodized Aluminum Substrate (Treatment Liquid: Sulfuric Acid)

### (A) Pretreatment (Electrolytic Polishing Treatment)

A high purity aluminum substrate (manufactured by Sumitomo Light Metal Industries, Ltd., purity: 99.99% by mass, thickness: 0.4 mm) was cut to a size which measured 10 cm on each of four sides, so as to be anodized, and the aluminum substrate was subjected to an electrolytic polishing treatment using an electrolytic polishing liquid having the following composition, under the conditions of a voltage of 25 V, a liquid temperature of 65° C., and a liquid flow rate of 3.0 m/min.

A carbon electrode was used as a cathode, and GP0110-30R (manufactured by Takasago, Ltd.) was used as a power supply. Furthermore, the flow rate of the liquid electrolyte was measured using a vortex type flow monitor, FLM22-10PCW (manufactured by AS ONE Corp.). ps (Electrolytic Polishing Liquid Composition)

85 mass % phosphoric acid (reagent manufactured by Wako Pure Chemical Industries, Ltd.) 660 mL

| | | |
|---|---|---|
| Pure water | 160 | mL |
| Sulfuric acid | 150 | mL |
| Ethylene glycol | 30 | mL |

### (B) Anodizing Treatment Process

Next, the aluminum substrate obtained after the electrolytic polishing treatment was subjected to an anodizing treatment for 5 hours using a liquid electrolyte of 0.30 mol/L sulfuric acid, under the conditions of a voltage of 25 V, a liquid temperature of 15° C., and a liquid flow rate of 3.0 m/min.

Subsequently, the aluminum substrate obtained after the anodizing treatment was subjected to a film removal treatment of immersing the aluminum substrate for 12 hours in a mixed aqueous solution (liquid temperature: 50° C.) of 0.2 mol/L anhydrous chromic acid and 0.6 mol/L phosphoric acid.

Subsequently, the aluminum substrate was subjected to a re-anodizing treatment for 3 hours using a liquid electrolyte of 0.30 mol/L sulfuric acid, under the conditions of a voltage of 25 V, a liquid temperature of 15° C., and a liquid flow rate of 3.0 m/min.

Meanwhile, for the anodizing treatment and the re-anodizing treatment, a stainless steel electrode was used as a cathode in both cases, and GP0110-30R (manufactured by Takasago, Ltd.) was used as a power source. Furthermore, NeoCool BD36 (manufactured by Yamato Scientific Co., Ltd.) was used as a cooling apparatus, and PAIRSTIRRER PS-100 (manufactured by EYELA Co.) was used as a stirring heating apparatus. Furthermore, the flow rate of the liquid electrolyte was measured using a vortex type flow monitor, FLM22-10PCW (manufactured by AS ONE Corp.).

For the porous structure of the anodized aluminum substrate thus obtained, the average pore diameter φ, the average pore spacing P, and the opening ratio (φ/P) were respectively measured and calculated by the method described below.

Images of the anodized aluminum surface were taken using an electron microscope. From the captured images, 20 openings were selected, the diameters were measured, and the average pore diameter φ was determined. Furthermore, the distances between the centers of two openings were measured, and the average pore spacing P and the opening ratio (φ/P) were calculated.

### Production Example 2

Production of anodized aluminum substrate (treatment liquid: oxalic acid)

### (A) Pretreatment Process (Electrolytic Polishing Treatment)

The process was carried out in the same manner as in (A) of Production Example 1.

### (B) Anodic Oxidation Film Forming Process (Anodizing Treatment)

The aluminum substrate obtained after the electrolytic polishing treatment was subjected to an anodizing treatment for one hour using a liquid electrolyte of 0.50 mol/L oxalic acid, under the conditions of a voltage of 40 V, a liquid temperature of 15° C., and a liquid flow rate of 3.0 m/min. Furthermore, the sample obtained after the anodizing treatment was subjected to a film removal treatment by immersing the sample for 25 minutes using a 0.5 mol/L aqueous phosphoric acid solution, under the conditions of 40° C.

These treatments were repeated 4 times in this sequence, and then the sample was subjected to a re-anodizing treatment for 4 hours using a liquid electrolyte of 0.50 mol/L oxalic acid, under the conditions of a voltage of 40 V, a liquid temperature of 15° C., and a liquid flow rate of 3.0 m/min, and was further subjected to a film removal treatment by immersing the sample for 25 minutes using a 0.5 mol/L aqueous phosphoric acid solution, under the conditions of 40° C. Thus, an anodic oxidation film in which micropores were arranged in a straight pipe shape and in a honeycomb arrangement, was formed on the aluminum substrate surface.

Meanwhile, for both the anodizing treatment and the re-anodizing treatment, a stainless steel electrode was used as a cathode, and GP0110-30R (manufactured by Takasago, Ltd.) was used as a power source. Furthermore, NeoCool BD36 (manufactured by Yamato Scientific Co., Ltd.) was used as a cooling apparatus, and PAIRSTIRRER PS-100 (manufactured by EYELA Co.) was used as a stirring heating apparatus. Furthermore, the flow rate of the liquid electrolyte was measured using a vortex type flow monitor, FLM22-10PCW (manufactured by AS ONE Corp.).

For the porous structure of the anodized aluminum substrate thus obtained, the average pore diameter φ, the average pore spacing P, and the opening ratio (φ/P) were respectively measured and calculated in the same manner as in Production Example 1.

### Example 1-1

### Producing of Thermoelectric Conversion Element

A thermoelectric conversion element was produced by using the anodized aluminum substrate obtained in Production Example 1 by a sulfuric acid treatment, and forming a thermoelectric conversion layer by a sputtering method.

A target formed from In₂O₃:90%-SnO₂:10% (ITO, purity: 4 N) was produced, and film forming was carried out using a magnetron sputtering apparatus. The film thickness of the thermoelectric conversion layer at this time was 150 nm.

The performance of the thermoelectric conversion layer thus formed was evaluated as described below. The results are shown in Table 1.

### Example 1-2

A thermoelectric conversion layer was formed on a substrate in the same manner as in Example 1-1, except that the substrate was changed to the anodized aluminum substrate obtained in Production Example 2 by an oxalic acid treatment, and the performance was evaluated. The results are shown in Table 1.

### Example 1-3

A thermoelectric conversion element was produced by using the anodized aluminum substrate obtained in Production Example 2 by an oxalic acid treatment, and forming a thermoelectric conversion layer by a sputtering method.

A target formed from In₂O₃:90%-ZnO:10% (IZO) was produced, and film forming was carried out using a magnetron sputtering apparatus. The film thickness of the thermoelectric conversion layer at this time was 200 nm.

The performance of the thermoelectric conversion layer thus formed was evaluated in the same manner as in Example 1-1. The results are shown in Table 1.

### Comparative Example 1-1

A thermoelectric conversion layer was formed on a substrate in the same manner as in Example 1-1, except that the substrate was changed to a quartz substrate, and the performance was evaluated. The results are shown in Table 1.

### [Measurement of Thermoelectric Characteristics]

Measurement was made in air atmosphere at a temperature of 100 degrees, using a thermoelectric characteristics analyzer, MODEL RZ2001i (product name, manufactured by Ozawa Science Co., Ltd.), and the Seebeck coefficient (V/k) and electrical conductivity (S/m) were measured.

### [Measurement of Thermal Conductivity]

A reflective layer (film thickness 100 nm) formed of molybdenum was formed on the thermoelectric conversion layer, and the thermal conductivity (W/(m·k)) was measured by a surface heating/surface temperature measurement method, using a thin film thermal properties analyzer, Pico TR (product name, manufactured by Pico Therm Corp.).

### [Evaluation of Thermoelectric Performance Factor Z]

From the Seebeck coefficient, electrical conductivity and thermal conductivity calculated as described above, a performance factor Z was calculated by the following numerical expression (A):

Numerical Expression (A): Z={(Seebeck Coefficient)²×(Electrical Conductivity)}/(Thermal Conductivity)

### [Evaluation of Void Structure]

The surface of the thermoelectric conversion layer was observed in a tapping mode using a scanning probe microscope, Nanopics 1000 (SII Nanotechnology, Inc.). The visual field range was set to 1000 nm, and the presence or absence of voids was confirmed from the surface unevenness of the surface.

TABLE 1

| | | | Porous | | | | Seebeck | | |
|---|---|---|---|---|---|---|---|---|---|
| | | | structure (nm) | | | Performance | coefficient | Void | Thermal conductivity |
| | Substrate | Treatment liquid | φ | P | φ/P | factor (Z) | (μV/k) | structure | (W/m · K) |
| Ex 1-1 | Anodized | Sulfuric acid | 40 | 63 | 0.63 | 3.41 × 10⁻⁵ | −19 | Presence | 0.72 |
| | aluminum | | | | | | | | |
| Ex 1-2 | Anodized | Oxalic acid | 60 | 100 | 0.6 | 3.46 × 10⁻⁵ | −29.8 | Presence | 0.59 |
| | aluminum | | | | | | | | |
| Ex 1-3 | Anodized | Oxalic acid | 60 | 100 | 0.6 | 6.8 × 10⁻⁵ | −21 | Presence | 0.68 |
| | aluminum | | | | | | | | |
| C Ex 1-1 | Quartz glass | — | — | — | — | 1.55 × 10⁻⁵ | −18.5 | Absence | 2.92 |

Ex means Example.
C Ex means Comparative Example.

As is clear from Table 1, the thermoelectric conversion layers in Examples 1-1 to 1-3 had a void structure, had low thermal conductivity and large absolute values of Seebeck coefficient, and exhibited excellent thermoelectric conversion performance. Particularly, in Example 1-2 in which a substrate treated by an oxalic acid was used, the absolute value of Seebeck coefficient was markedly increased. On the contrary, in Comparative Example 1-1 in which a quartz substrate was used, the thermoelectric performance was significantly lower than that of Examples 1-1 to 1-3.

### Example 2-1

### Producing of Thermoelectric Conversion Element

A thermoelectric conversion element was produced by using an anodized aluminum substrate obtained in Production Example 1 by a sulfuric acid treatment, and forming a thermoelectric conversion layer by a sputtering method.

A target formed of Zn₄Sb₃ (zinc antimonide) was produced, and film forming was carried out using a magnetron sputtering apparatus, while maintaining the temperature of the substrate at 150° C. The film thickness of the thermoelectric conversion layer at this time was 200 nm. Furthermore, an annealing treatment was carried out for 4 hours at 350° C. using an electric furnace purged with argon gas, and thus a thermoelectric conversion layer was formed.

The performance of the thermoelectric conversion layer was evaluated as follows. The results are shown in Table 2-1.

### Example 2-2

A thermoelectric conversion layer was formed on a substrate in the same manner as in Example 2-1, except that the substrate was changed to the anodized aluminum substrate obtained in Production Example 2 by an oxalic acid treatment, and the performance was evaluated. The results are shown in Table 2-1.

### Comparative Example 2-1

A thermoelectric conversion layer was formed on a substrate in the same manner as in Example 2-1, except that the substrate was changed to a quartz substrate, and the performance was evaluated. The results are shown in Table 2-1.

### Comparative Examples 2-2 to 2-3

A thermoelectric conversion layer was formed on a substrate in the same manner as in Example 2-2, except that the various materials indicated in Table 2-2 were used instead of Zn₄Sb₃ as the thermoelectric conversion material, and the temperature and time for the annealing treatment were changed to the conditions indicated in Table 2-2, and the performance was evaluated. The results are shown in Table 2-2. Meanwhile, Bi has a melting point of 271° C.

### [Evaluation of Thermoelectric Performance]

Measurement was made in air atmosphere at a temperature of 100 degrees using a thermoelectric characteristics analyzer, MODEL RZ2001i (product name, manufactured by Ozawa Science Co., Ltd.), and the thermopower (Seebeck coefficient: V/k) and electrical conductivity (S/m) were measured. From the Seebeck coefficient and electrical conductivity thus obtained, Power Factor (PF) was calculated by the following numerical expression:

PF=(Seebeck coefficient)×(electrical conductivity)

### [Evaluation of Void Structure]

The surface of the thermoelectric conversion layer was observed in a tapping mode using a scanning probe microscope, Nanopics 1000 (SII Nanotechnology, Inc.). The visual field range was set to 1000 nm, and the presence or absence of voids was confirmed from the surface unevenness of the surface.

### [Evaluation of Adhesiveness]

A tape peeling test using a Cellophane tape was carried out, and a sample in which no detachment of the thermoelectric conversion layer was observed was rated as ◯, and a sample in which detachment was observed was rated as ×.

TABLE 2-1

| | | | Porous structure | | | | Thermoelectric | | |
|---|---|---|---|---|---|---|---|---|---|
| | | Treatment | (nm) | | | Annealing | performance* | Void | |
| | Substrate | liquid | φ | P | φ/P | treatment | (PF) | structure | Adhesiveness |
| Ex 2-1 | Anodized aluminum | Sulfuric acid | 40 | 63 | 0.63 | 350° C. × 4 h | 320 | Presence | ∘ |
| Ex 2-2 | Anodized aluminum | Oxalic acid | 60 | 100 | 0.6 | 350° C. × 4 h | 384 | Presence | ∘ |
| C Ex 2-1 | Quartz glass | — | — | — | — | 350° C. × 4 h | 104 | Absence | x |

*Power Factor (Power Factor): μW/(m · K²) (Measured temperature: 100° C.)
Ex means Example.
C Ex means Comparative Example.

TABLE 2-2

| | | | | Porous | | | | |
|---|---|---|---|---|---|---|---|---|
| | Thermoelectric | | | structure (nm) | | | Annealing | Void |
| | conversion material | Substrate | Treatment liquid | φ | P | φ/P | treatment | structure |
| C Ex 2-2 | BiSbTe | Anodized aluminum | Oxalic acid | 60 | 100 | 0.6 | 350° C. × 2 h | Absence |
| C Ex 2-3 | BiSbTe | Anodized aluminum | Oxalic acid | 60 | 100 | 0.6 | 400° C. × 2 h | Absence |

Ex means Example.
C Ex means Comparative Example.

As is clear from Tables 2-1 and 2-2, in Examples 2-1 and 2-2 in which an anodized aluminum substrate was used, a void structure was formed inside the thermoelectric conversion layer. On the contrary, in Comparative Example 2-1 in which a quartz substrate was used, a void structure was not formed. Furthermore, Examples 2-1 and 2-2 exhibited excellent thermoelectric performance, and the adhesiveness to the substrate was also satisfactory. In Comparative Example 2-1 in which a quartz substrate was used, even though an annealing treatment was carried out, the thermoelectric performance was significantly lower than that of Examples 2-1 and 2-2.

In Comparative Examples 2-2 and 2-3 in which a thermoelectric conversion layer was formed using an element having a low melting point, a void structure of the conversion layer was not confirmed. It is presumed that this is because the element having a low melting point melted by the annealing treatment, and the void structure of the conversion layer was lost. Furthermore, in Comparative Example 2-3, metallic gloss was lost as compared with the state before the annealing treatment, and the specific resistance of the thermoelectric conversion layer increased infinitely. It is presumed that this is because tellurium contained in the conversion layer sublimed.

### Example 2-3

A thermoelectric conversion element was produced using the anodized aluminum substrate obtained in Production Example 2 by an oxalic acid treatment, and forming a thermoelectric conversion layer by a sputtering method.

A target formed of CoSb₃ (cobalt antimonide) was produced, and film forming was carried out using a magnetron sputtering apparatus while maintaining the temperature of the substrate at 150° C. The film thickness of the thermoelectric conversion layer at this time was 200 nm. An annealing treatment for 2 hours at 350° C. using an electric furnace purged with argon gas, a thermoelectric conversion layer was formed, and the performance was evaluated.

The results are shown in Table 2-3.

### Example 2-4

A thermoelectric conversion element was produced using the anodized aluminum substrate obtained in Production Example 2 by an oxalic acid treatment, and forming a thermoelectric conversion layer by a sputtering method.

A target formed of MnSi_{1.75} (manganese silicide) was produced, and film forming was carried out using a magnetron sputtering apparatus while maintaining the temperature of the substrate at 150° C. The film thickness of the thermoelectric conversion layer at this time was 200 nm. An annealing treatment for 2 hours at 350° C. using an electric furnace purged with argon gas, a thermoelectric conversion layer was formed, and the performance was evaluated.

The results are shown in Table 2-3.

### Example 2-5

A thermoelectric conversion element was produced using the anodized aluminum substrate obtained in Production Example 2 by an oxalic acid treatment, and forming a thermoelectric conversion layer by a sputtering method.

A target formed of FeSi₂ (iron silicide) was produced, and film forming was carried out using a magnetron sputtering apparatus while maintaining the temperature of the substrate at 150° C. The film thickness of the thermoelectric conversion layer at this time was 200 nm. An annealing treatment for 2 hours at 350° C. using an electric furnace purged with argon gas, a thermoelectric conversion layer was formed, and the performance was evaluated. The results are shown in Table 2-3.

### Comparative Example 2-4

A thermoelectric conversion element was produced in the same manner as in Example 2-3, except that a quartz glass plate was used instead of an anodized aluminum substrate, and the performance was evaluated. The results are shown in Table 2-3.

TABLE 2-3

| | | | Porous | | | | Thermoelectric | | |
|---|---|---|---|---|---|---|---|---|---|
| | | | structure (nm) | | | Annealing | performance* | Void | |
| | Substrate | Treatment liquid | φ | P | φ/P | treatment | (PF) | structure | Adhesiveness |
| Ex 2-3 | Anodized aluminum | Oxalic acid | 60 | 100 | 0.6 | 350° C. × 2 h | 0.53 | Presence | ∘ |
| Ex 2-4 | Anodized aluminum | Oxalic acid | 60 | 100 | 0.6 | 350° C. × 2 h | 1.03 | Presence | ∘ |
| Ex 2-5 | Anodized aluminum | Oxalic acid | 60 | 100 | 0.6 | 350° C. × 2 h | 2.82 | Presence | ∘ |
| C Ex 2-4 | Quartz glass | — | — | — | — | 350° C. × 2 h | 0.13 | Absence | x |

*Power Factor (Power Factor): μW/(m · K²) (Measured temperature: 100° C.)
Ex means Example.
C Ex means Comparative Example.

As is clear from Table 2-3, in Examples 2-3 to 2-5 in which anodized aluminum substrates were used, a void structure was formed inside the thermoelectric conversion layer, and the adhesiveness to the substrate was also satisfactory. Furthermore, also for the thermoelectric conversion performance, although the performance was lower than that of the thermoelectric conversion material Zn₄Sb₃ (Table 2-1), satisfactory thermoelectric conversion performance was exhibited.

On the contrary, in Comparative Example 2-4 in which a quartz substrate was used, a void structure was not formed, and the adhesiveness to the substrate was also poor. Furthermore, the thermoelectric conversion performance was also inferior compared with Example 3.

Having described our invention as related to the present embodiments, it is our intention that the invention not be limited by any of the details of the description, unless otherwise specified, but rather be construed broadly within its spirit and scope as set out in the accompanying claims.

This application claims priority on Patent Application No. 2011-229554 filed in Japan on Oct. 19, 2011, and Patent Application No. 2011-229555 filed in Japan on Oct. 19, 2011 each of which is entirely herein incorporated by reference.

### REFERENCE SIGNS LIST

1: Thermoelectric conversion element
2: Aluminum substrate
3, 13, 23: Anodic oxidation film
4: Thermoelectric conversion layer
15, 25: Micropores
26: Thermoelectric conversion material

1. thermoelectric conversion element formed by laminating, on a substrate having a porous anodic oxidation film of aluminum,
a thermoelectric conversion layer which contains an inorganic oxide semiconductor or an element having a melting point of 300° C. or higher, as a main component, and which has a void structure.

2. The thermoelectric conversion element according to claim 1, wherein the inorganic oxide semiconductor contains indium.

3. The thermoelectric conversion element according to claim 1, wherein the inorganic oxide semiconductor is selected from the group consisting of In₂O₃, SnO₂, ZnO, SrTiO₃, WO₃, MoO₃, In₂O₃—SnO₂, fluorine-doped tin oxide, antimony-doped tin oxide, antimony-doped zinc oxide, gallium-doped zinc oxide, In₂O₃—ZnO, and gallium-doped In₂O₃—ZnO.

4. The thermoelectric conversion element according to claim 1, wherein the thermoelectric conversion layer contains an element having a melting point of 330° C. or higher as a main component.

5. The thermoelectric conversion element according to any one of claim 1, wherein the thermoelectric conversion layer contains an alloy selected from the group consisting of Zn₄Sb₃, CoSb₃, MnSi_{1.75}, Mg₂Si, SiGe and FeSi₂ as a main component.

6. The thermoelectric conversion element according to claim 1, wherein an opening ratio of the porous anodic oxidation film satisfies the following numerical expression (I):
Numerical expression (I)
Opening ratio=φ/P>0.5
wherein φ represents an average pore diameter; and P represents an average pore spacing.

7. The thermoelectric conversion element according to claim 1, wherein the average pore diameter of the pores of the porous anodic oxidation film is 60 nm or larger.

8. A method of producing a thermoelectric conversion element, comprising a step of forming a film of a thermoelectric conversion material which contains an inorganic oxide semiconductor or an element having a melting point of 300° C. or higher as a main component, on a substrate having a porous anodic oxidation film of aluminum, to form a thermoelectric conversion layer.

9. The method of producing a thermoelectric conversion element according to claim 8, comprising steps of;
forming a film of a thermoelectric conversion material which contains an element having a melting point of 300° C. or higher as a main component, on a substrate having a porous anodic oxidation film of aluminum, to form a thermoelectric conversion layer; and
annealing the thermoelectric conversion layer.

10. The method of producing a thermoelectric conversion element according to claim 8, comprising a step of forming a film of a thermoelectric conversion material which contains an element having a melting point of 300° C. or higher as a main component, at a substrate temperature of 150° C. or higher, on a substrate having a porous anodic oxidation film of aluminum, to form a thermoelectric conversion layer.

11. The method of producing a thermoelectric conversion element according to claim 8, comprising a step of anodizing an aluminum plate with oxalic acid, to obtain the substrate having the porous anodic oxidation film.

12. The method of producing a thermoelectric conversion element according to claim 8, wherein the film forming process is carried out by a vapor phase deposition method.
